(19) United States
(12) Patent Application Publication
(10) Pub. No.: US 2015/0021748 A1
(43) Pub. Date: Jan. 22, 2015

(54) SEMICONDUCTOR DEVICE

(71) Applicant: Kabushiki Kaisha Toshiba, Minato-ku (JP)

(72) Inventors: Tadahiro SASAKI, Nerima-ku (JP); Kazuhiko Itaya, Yokohama-shi (JP); Hiroshi Yamada, Yokohama-shi (JP); Yutaka Onozuka, Yokohama-shi (JP); Nobuto Managaki, Kawasaki-shi (JP)

(73) Assignee: Kabushiki Kaisha Toshiba, Minato-ku (JP)

(21) Appl. No.: 14/332,542

(22) Filed: Jul. 16, 2014

(30) Foreign Application Priority Data
Jul. 19, 2013 (JP) 2013-151079

(51) Int. Cl. H01L 23/66; H01L 23/053

(52) U.S. Cl. CPC H01L 23/66; H01L 23/053; H01L 2223/6616
USPC 257/664

(57) ABSTRACT

A semiconductor device of an embodiment includes: a substrate, a high-frequency integrated circuit being provided on the substrate, a cap, and a sealing wall provided between the substrate and the cap. The cap includes a first conductive layer, a second conductive layer, an insulating layer provided between the first conductive layer and the second conductive layer, and a conductive via provided in the insulating layer. The conductive via connects the first conductive layer and the second conductive layer. The first conductive layer or the second conductive layer is connected to a ground potential. The sealing wall surrounds the high-frequency integrated circuit.

### CROSS-REFERENCE TO RELATED APPLICATION

This application is based upon and claims the benefit of priority from Japanese Patent Application No. 2013-151079, filed on Jul. 19, 2013, the entire contents of which are incorporated herein by reference.

### FIELD

Embodiments described herein relate generally to a semiconductor device.

### BACKGROUND

Semiconductor chips provided with high-frequency circuits and circuit boards on which high-frequency integrated circuits are provided are hermetically sealed in order to protect circuits and suppress noise. For hermetic sealing, for example, a semiconductor chip or a circuit board is covered with a cap, and, in addition, a sealing wall is formed between the semiconductor chip or the circuit board and the cap around the circuits. A cavity that is an airtight space is formed between the circuits and the cap. The cap, for example, is formed from a low-resistance metal in order to flow a return current.

However, in high-frequency circuits of 1 GHz or more, for example, there is a problem that the insertion loss of signal lines increases because of a local increase in the resistance of the metal cap caused by an induced current. Thus, a high-frequency semiconductor device that has a simple structure and is airtight, and reduces insertion loss is required.

### BRIEF DESCRIPTION OF THE DRAWINGS

FIG. 1 is a schematic cross-sectional view of a semiconductor device of a first embodiment;

FIG. 2 is a perspective conceptual view of the semiconductor device of the first embodiment;

FIG. 3 is a schematic cross-sectional view of a semiconductor device of a second embodiment; and

FIG. 4 is the result of an insertion loss simulation for the semiconductor device of the second embodiment.

### DETAILED DESCRIPTION

A semiconductor device of an embodiment including: a substrate, a high-frequency integrated circuit being provided on the substrate; a cap including a first conductive layer, a second conductive layer, an insulating layer provided between the first conductive layer and the second conductive layer, and a conductive via provided in the insulating layer, the conductive via connecting the first conductive layer and the second conductive layer, wherein the first conductive layer or the second conductive layer is connected to a ground potential; and a sealing wall provided between the substrate and the cap, the sealing wall surrounding the high-frequency integrated circuit.

It should be noted that, in the present description, a high-frequency circuit or a high-frequency integrated circuit means a circuit or an integrated circuit that operates at a frequency band of 100 MHz or more.

### First Embodiment

A semiconductor device of the present embodiment including: a substrate, a high-frequency integrated circuit being provided on the substrate; a cap including a first conductive layer, a second conductive layer, an insulating layer provided between the first conductive layer and the second conductive layer, and a conductive via provided in the insulating layer, the conductive via connecting the first conductive layer and the second conductive layer, wherein the first conductive layer or the second conductive layer is connected to a ground potential; and a sealing wall provided between the substrate and the cap, the sealing wall surrounding the high-frequency integrated circuit.

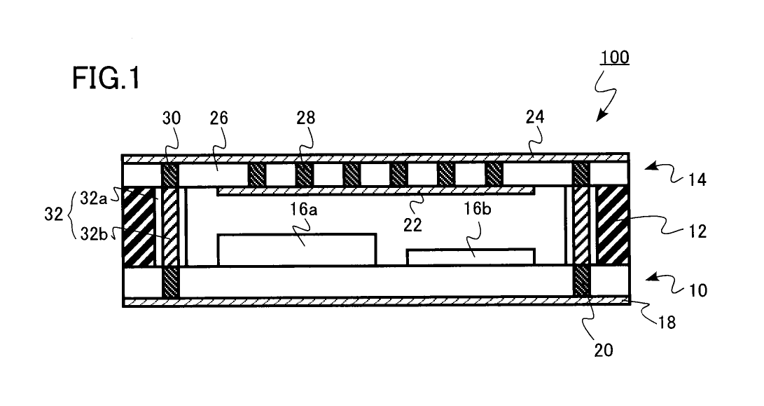

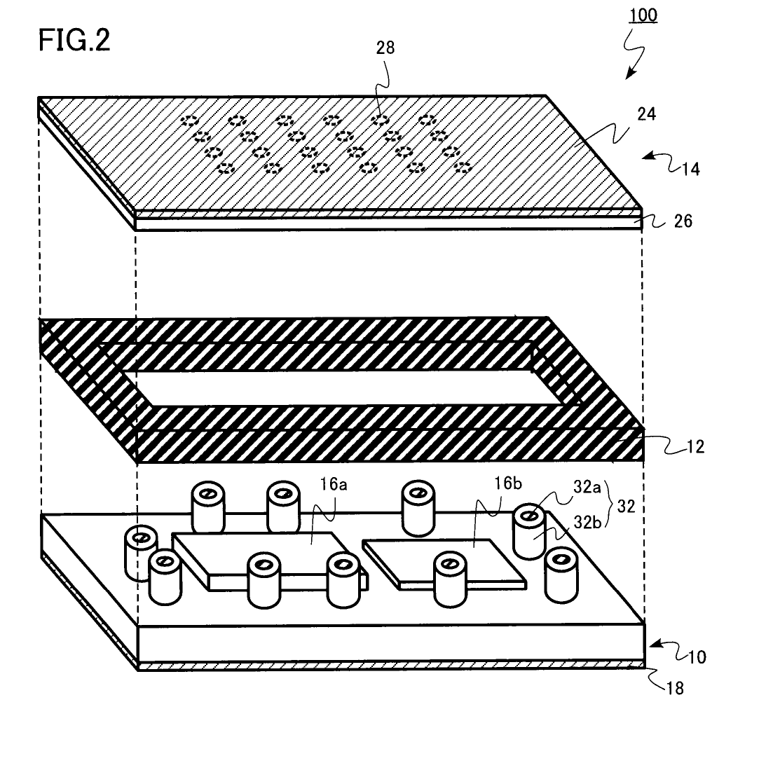

FIG. 1 is a schematic cross-sectional view of the semiconductor device of the present embodiment. FIG. 2 is a perspective conceptual view of the semiconductor device of the present embodiment.

A semiconductor device 100 is, for example, a semiconductor module for communication that operates at a frequency band of approximately 2 GHz. The semiconductor device 100 has, for example, a size that is approximately 15 mm×2 mm in length and width, and is approximately 5 mm in height. The semiconductor device 100 is provided with a substrate 10, a sealing wall 12, and a cap 14.

The substrate 10 is, for example, a printed board in which wiring is printed on a resin sheet. A first semiconductor chip 16a and a second semiconductor chip 16b are mounted on the substrate 10. The first semiconductor chip 16a and the second semiconductor chip 16b are components of a high-frequency integrated circuit provided on the substrate 10. The first semiconductor chip 16a and the second semiconductor chip 16b may be bare chips or may be mounted chips.

A metal conductive layer (third conductive layer) 18 is formed on the rear surface of the substrate 10. The conductive layer 18 is connected to the ground potential. Through-vias 20 that pass through the substrate 10 and connect to the conductive layer 18 are formed in the substrate 10.

The substrate 10 may be a multilayer substrate. Furthermore, the conductive layer 18, which is connected to the ground potential, may be a conductive layer within a multilayer substrate rather than on the rear surface of the substrate 10. Furthermore, for example, it is possible to employ a ceramic substrate for the substrate 10.

Furthermore, a configuration in which yet another substrate is laminated under the substrate 10 may be implemented. In such case, a sealing wall is provided also between the substrate 10 and the other substrate and hermetic sealing is implemented.

The sealing wall 12 is provided between the substrate 10 and the cap 14 in such a way as to surround the high-frequency integrated circuit. The sealing wall 12 forms a cavity between the substrate 10 and the cap 14. The high-frequency integrated circuit is protected from external moisture and so forth and has improved reliability because of being hermetically sealed in the cavity.

The sealing wall 12 is, for example, formed of a resin. By using a resin, the sealing wall 12 is able to be formed in an inexpensive and simple manner, and to ensure the insulation properties of input/output lines easily. The sealing wall 12 may be formed of a ceramic or a metal as long as hermetic sealing is possible.

For example, input/output lines are formed by a conductive layer formed on the substrate 10 or in the substrate 10. Input/output signals are sent to the first semiconductor chip 16a and the second semiconductor chip 16b from outside of the cavity by means of the input/output lines.

The cap 14 is provided at the high-frequency integrated circuit side of the substrate 10 in order to protect the high-frequency integrated circuit. The cap 14 is provided with a first conductive layer 22, a second conductive layer 24, and an insulating layer 26 between the first conductive layer 22 and the second conductive layer 24. Furthermore, conductive vias 28 that are provided in the insulating layer 26 and electrically connect the first conductive layer 22 and the second conductive layer 24 are provided. Furthermore, conductive through-vias 30 are provided in the insulating layer 26.

The first conductive layer 22 and the second conductive layer 24 are, for example, a metal. The first conductive layer 22 and the second conductive layer 24 are, for example, gold (Au) or copper (Cu). The insulating layer 26 is, for example, a resin.

The vias 28 are, for example, a metal. The vias 28 are, for example, gold (Au) or copper (Cu).

The cap 14 has an electromagnetic band gap (EBG) construction. The cap 14 functions as a low-pass filter by means of a capacitance component between the first conductive layer 22 and the second conductive layer 24, and an inductor component by the vias 28.

In the present embodiment, the first conductive layer 22 is provided on the substrate 10 side of the cap 14, and the second conductive layer 24 is provided on the opposite side of the cap 14 to the substrate 10. The second conductive layer 24 is connected to the ground potential. The first conductive layer 22 is indirectly connected to the ground potential by way of the vias 28.

The second conductive layer 24 at the opposite side to the high-frequency integrated circuit is directly connected to the ground potential, and the first conductive layer 22 that faces the high-frequency integrated circuit is indirectly connected to the ground potential. As a result of this configuration, it is possible to suppress undesired resonance to occur and the frequency characteristics of the semiconductor device 100 to deteriorate.

The third conductive layer 18 and the first or second conductive layer 22 or 24 are connected by way of a conductive material provided between the substrate 10 and the cap 14. Specifically, for example, connection spacers 32 that have a conductive section 32b surrounded by an insulating section 32a are employed. For example, the third conductive layer 18 and the second conductive layer 24 are electrically conducted by way of the through-vias 20, the connection spacers 32, and the through-vias 30.

The connection spacers 32 are also provided with the function of supporting the cap 14 on the substrate 10. For example, it is possible for the sealing wall 12 to be formed with ease by applying a resin at the outer edge section between the substrate 10 and the cap 14 supported by the connection spacers 32.

According to the present embodiment, by using the cap 14 having an EBG structure, it becomes possible to reduce signal insertion loss and unnecessary oscillation of the high-frequency integrated circuit. Namely, for example, the local generation of induced current is able to be suppressed even when unnecessary noise (electromagnetic waves) is locally transmitted to the cap from the high-frequency integrated circuit. Accordingly, local increases in the resistance of the cap 14 are suppressed. Therefore, deviation in the impedance of the cap 14 decreases, and increases in insertion loss and unnecessary oscillation of the high-frequency integrated circuit are suppressed.

Furthermore, by using the cap 14 having an EBG structure, it is possible to suppress a negative effect on the operation of the internal high-frequency integrated circuit affected by external noise. Furthermore, it is possible to suppress a negative effect on circuits outside of the semiconductor device 100 affected by the noise which occurs because of the operation of the high-frequency integrated circuit. Furthermore, it becomes also possible to suppress signal line insertion loss at input/output units for the semiconductor device 100 without implementing a complicated structure.

As described above, according to the present embodiment, a high-frequency semiconductor device that has a simple structure and is airtight, is small, and reduces insertion loss is realized. Furthermore, a high-frequency semiconductor device that is able to operate in a stable manner and also suppress negative effects on the outside is realized.

### Second Embodiment

A semiconductor device of the present embodiment including: a semiconductor substrate, a high-frequency circuit being provided on the substrate; a cap including a first conductive layer, a second conductive layer, an insulating layer provided between the first conductive layer and the second conductive layer, and a via provided in the insulating layer, the via connecting the first conductive layer and the second conductive layer, wherein the first conductive layer or the second conductive layer is connected to a ground potential; and a sealing wall provided between the semiconductor substrate and the cap, the sealing wall surrounding the high-frequency circuit.

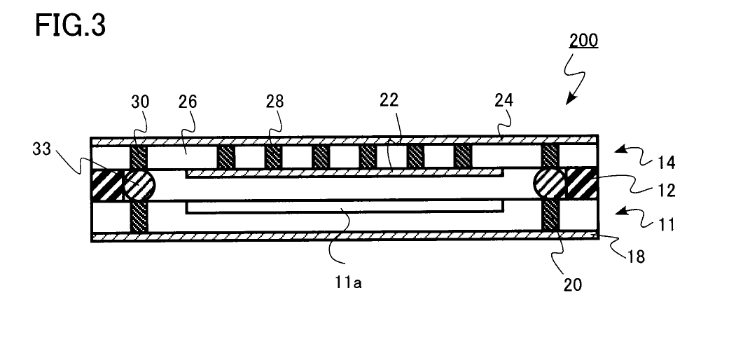

FIG. 3 is a schematic cross-sectional view of the semiconductor device of the present embodiment.

A semiconductor device 200 is, for example, a power amplifier that operates at a frequency band of approximately 6 to 8 GHz. The semiconductor device 200 is, for example, a gallium arsenide (GaAs) semiconductor chip.

The semiconductor device 200 has, for example, a size that is 2 mm×2 mm. The semiconductor device 200 is provided with a semiconductor substrate 11, a sealing wall 12, and a cap 14.

The semiconductor substrate 11 is, for example, a GaAs substrate. A high-frequency circuit 11a in which a transistor and so forth is used is formed on the semiconductor substrate 11.

A metal conductive layer (third conductive layer) 18 is formed on the rear surface of the semiconductor substrate 11. The conductive layer 18 is connected to the ground potential. Through-vias 20 that pass through the semiconductor substrate 11 and connect to the conductive layer 18 are formed in the semiconductor substrate 11.

The semiconductor substrate 11 may be a semiconductor substrate other than a GaAs substrate such as a silicon (Si) substrate as long as it is possible for a high-frequency circuit to be formed.

The sealing wall 12 is provided between the semiconductor substrate 11 and the cap 14 in such a way as to surround the high-frequency circuit. The sealing wall 12 forms a cavity between the semiconductor substrate 11 and the cap 14. The high-frequency circuit is protected from external moisture and so forth and has improved reliability due to being hermetically sealed in the cavity.

The sealing wall 12 is, for example, formed of a resin. By using a resin, the sealing wall 12 is able to be formed in an inexpensive and simple manner, and to ensure the insulation properties of input/output lines easily. The sealing wall 12 may be formed of a ceramic or a metal as long as hermetic sealing is possible.

For example, in the high-frequency circuit 11a, input/output lines are formed by a conductive layer formed on the semiconductor substrate 11. Input/output signals are sent to the high-frequency circuit 11a from outside of the cavity by means of the input/output lines.

The cap 14 is provided at the high-frequency circuit side of the semiconductor substrate 11 in order to protect the high-frequency circuit. The cap 14 is provided with a first conductive layer 22, a second conductive layer 24, and an insulating layer 26 between the first conductive layer 22 and the second conductive layer 24. Furthermore, conductive vias 28 that are provided in the insulating layer 26 and electrically connect the first conductive layer 22 and the second conductive layer 24 are provided. Furthermore, conductive through-vias 30 are provided in the insulating layer 26.

The first conductive layer 22 and the second conductive layer 24 are, for example, a metal. The first conductive layer 22 and the second conductive layer 24 are, for example, gold (Au) or copper (Cu). The insulating layer 26 is, for example, a high-resistance silicon.

The vias 28 are, for example, a metal. The vias 28 are, for example, gold (Au) or copper (Cu).

The cap 14 has an electromagnetic band gap (EBG) construction. The cap 14 functions as a low-pass filter by means of a capacitance component between the first conductive layer 22 and the second conductive layer 24, and an inductor component afforded by the vias 28.

In the present embodiment, the first conductive layer 22 is provided on the semiconductor substrate 11 side of the cap 14, and the second conductive layer 24 is provided on the opposite side of the cap 14 to the semiconductor substrate 11. The second conductive layer 24 is then connected to the ground potential. The first conductive layer 22 is indirectly connected to the ground potential by way of the vias 28.

The second conductive layer 24 at the opposite side to the high-frequency circuit is directly connected to a direct ground potential, and the first conductive layer 22 that faces the high-frequency circuit is indirectly connected to a ground potential. As a result of this configuration, it is possible to suppress undesired resonance to occur and the frequency characteristics of the semiconductor device 200 to deteriorate.

The third conductive layer 18 and the first or second conductive layer 22 or 24 are connected by way of a conductive material provided between the semiconductor substrate 11 and the cap 14. Specifically, for example, solder bumps 33 are used. For example, the third conductive layer 18 and the second conductive layer 24 electrically conduct by way of the through-vias 20, the solder bumps 33, and the through-vias 30.

The solder bumps 33 are also provided with the function of supporting the cap 14 on the semiconductor substrate 11. For example, it is possible for the sealing wall 12 to be formed with ease by applying a resin at the outer edge section between the semiconductor substrate 11 and the cap 14 supported by the solder bumps 33.

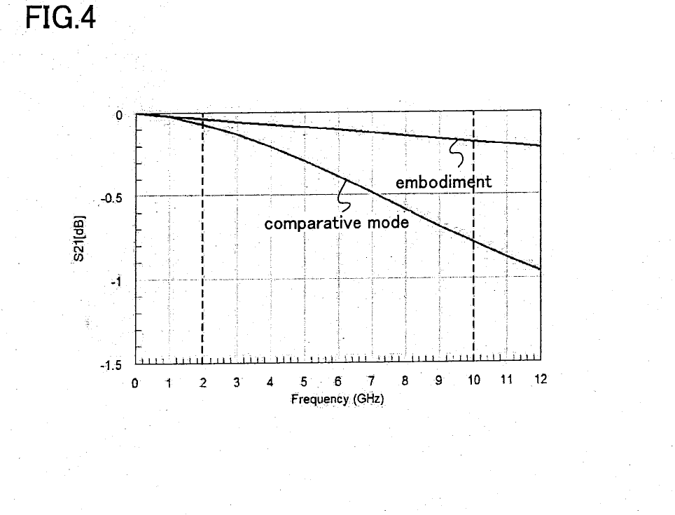

FIG. 4 is the result of an insertion loss simulation for the semiconductor device of the present embodiment. The frequency dependence of the insertion loss (S21) of a signal line is depicted. The X-axis indicates frequency, and the Y-axis indicates the insertion loss (S21) of the signal line. The characteristics of the present embodiment and a comparative mode are compared.

The cap 14 was 2 mm×2 mm, and the insulating layer 26 was a high-resistance silicon with a thickness of 100 μm and a dielectric constant of 10.5. The first conductive layer 22 and the second conductive layer 24 were metal sheets. The vias 28 were 50 μm×50 μm in size, and were arranged in a 20×20 matrix with 50 μm pitches.

The semiconductor substrate 11 was a GaAs substrate having a thickness of 80 μm. The GaAs substrate had a microstrip structure in which the rear surface was fixed to the ground potential. A microstrip line having a width of 100 μm was provided as a signal line on the front surface of the GaAs substrate.

The distance between the semiconductor substrate 11 and the cap 14, namely the height of the cavity, was 50 μm. Furthermore, the second conductive layer 24 was fixed directly to the ground potential, and the first conductive layer 22 was fixed to the ground potential by way of the vias 28.

On the other hand, in the comparative mode, in contrast to the embodiment, the first conductive layer 22 and the insulating layer 26 were omitted, and only the metal-sheet second conductive layer 24 was implemented.

At a frequency of 2 GHz, in contrast to the comparative mode in which the insertion loss was −0.07 dB, an improvement was made to −0.039 dB in the present embodiment. In the case of a frequency of 10 GHz, in contrast to −0.78 dB in the comparative mode, an improvement was made to −0.17 dB in the present embodiment.

In this way, according to the present embodiment, in particular, insertion loss at a high frequency band is able to be suppressed. Furthermore, in the present embodiment, although the transition at around cutoff frequency is not steep, a low-pass filter effect is demonstrated.

According to the present embodiment, by using the cap 14 having an EBG structure, it becomes possible to reduce signal insertion loss and unnecessary oscillation of the high-frequency circuit. Namely, for example, the local generation of induced current is able to be suppressed even when unnecessary noise (electromagnetic waves) is locally transmitted to the cap from the high-frequency circuit. Accordingly, local increases in the resistance of the cap 14 are suppressed. Therefore, deviation in the impedance of the cap decreases, and increases in insertion loss and unnecessary oscillation of the high-frequency circuit are suppressed.

Furthermore, by using the cap 14 having an EBG structure, it is possible to suppress a negative effect on the operation of the internal high-frequency circuit affected by external noise. Furthermore, it is possible to suppress a negative effect on the circuits outside of the semiconductor device 200 affected by the noise which occurs because of the operation of the high-frequency circuit. Furthermore, it becomes also possible to suppress signal line insertion loss at input/output units for the semiconductor device 200 without implementing a complicated structure.

As described above, according to the present embodiment, a high-frequency semiconductor device that has a simple structure and is airtight, is small, and reduces insertion loss is realized. Furthermore, a high-frequency semiconductor device that is able to operate in a stable manner and also suppress negative effects on the outside is realized.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate, a high-frequency integrated circuit being provided on the substrate;
a cap including
a first conductive layer,
a second conductive layer,
an insulating layer provided between the first conductive layer and the second conductive layer, and
a conductive via provided in the insulating layer, the conductive via connecting the first conductive layer and the second conductive layer,
wherein the first conductive layer or the second conductive layer is connected to a ground potential; and
a sealing wall provided between the substrate and the cap, the sealing wall surrounding the high-frequency integrated circuit.

2. The device according to claim 1, wherein the first conductive layer is provided on the substrate side of the cap, the second conductive layer is provided on the opposite side of the cap to the substrate, the second conductive layer is connected to the ground potential, and the first conductive layer is connected to the ground potential by way of the conductive via.

3. The device according to claim 1, wherein the substrate includes a third conductive layer connected to the ground potential, and the third conductive layer and the first or second conductive layer are connected by way of a conductive material provided between the substrate and the cap.

4. The device according to claim 1, wherein the insulating layer is a resin.

5. The device according to claim 1, wherein the substrate is a printed board.

6. The device according to claim 1, wherein the first and second conductive layers are a metal.

7. The device according to claim 1, wherein the high-frequency integrated circuit includes a plurality of semiconductor chips.

8. The device according to claim 1, wherein the sealing wall is a resin.

9. The device according to claim 1, wherein the substrate is a multilayer printed board.

10. The device according to claim 1, wherein the conductive via is a metal.

11. A semiconductor device comprising:
a semiconductor substrate, a high-frequency circuit being provided on the substrate;
a cap including
a first conductive layer,
a second conductive layer,
an insulating layer provided between the first conductive layer and the second conductive layer, and
a via provided in the insulating layer, the via connecting the first conductive layer and the second conductive layer,
wherein the first conductive layer or the second conductive layer is connected to a ground potential; and
a sealing wall provided between the semiconductor substrate and the cap, the sealing wall surrounding the high-frequency circuit.

12. The device according to claim 11, wherein the first conductive layer is provided on the semiconductor substrate side of the cap, the second conductive layer is provided on the opposite side of the cap to the semiconductor substrate, the second conductive layer is connected to the ground potential, and the first conductive layer is connected to the ground potential by way of the via.

13. The device according to claim 11, wherein the semiconductor substrate includes a third conductive layer connected to the ground potential, and the third conductive layer and the first or second conductive layer are connected by way of a conductive material provided between the semiconductor substrate and the cap.

14. The device according to claim 11, wherein the insulating layer is a high-resistance silicon.

15. The device according to claim 11, wherein the semiconductor substrate is a gallium arsenide (GaAs) substrate.

16. The device according to claim 11, wherein the first and second conductive layers are a metal.

17. The device according to claim 11, wherein the sealing wall is a resin.

18. The device according to claim 13, wherein the conductive material is a solder bump.

19. The device according to claim 11, wherein the via is a metal.

20. The device according to claim 11, wherein the first and second conductive layers are gold (Au).
